(19) United States
(12) Patent Application Publication
(10) Pub. No.: US 2007/0258202 A1
(43) Pub. Date: Nov. 8, 2007

(54) Power-over-Ethernet sourcing device with input-power pass through

(75) Inventors: Shaun Patrick Cooley, El Segundo, CA (US); Brain Christopher Powell, El Segundo, CA (US)

Correspondence Address: David W. Lynch;Chambliss, Bahner & Stophel, P.C., 1000 Tallan Building, Two Union Square, Chattanooga, TN, 37402, US

(73) Assignee: SB Wireless, LLC

(21) Appl. No.: 11/429,885

(22) Filed: May 8, 2006

(51) Int. Cl. H05K 5/00

(52) U.S. Cl. 361/683

(57) ABSTRACT

A Power-over-Ethernet (PoE) power sourcing equipment that is connected to an existing power supply and provides pass-through power for additional devices. The Power-over-Ethernet (PoE) power sourcing equipment eases the installation of PoE sourcing equipment in locations where networking infrastructure is not already in place. Further, the PoE sourcing equipment according to an embodiment of the present invention will not monopolize potentially valuable outlets. To further expand the use of many power-over-Ethernet devices at the same location, the appliance allows layered installation to facilitate multiple deployments simultaneously.

### BACKGROUND OF THE INVENTION

1. Field of the Invention.

This invention relates to power sourcing equipment (PSE) for supplying power to power-over-Ethernet (PoE) powered devices (PD), and more particularly, to PoE power sourcing equipment that is connected to an existing power supply and provides pass-through power for additional devices.

2. Description of Related Art.

In recent years, the rapid expansion of the Internet has led to the development of many new products and services. The most recognized impact of the Internet is in the availability of public and private information that is readily available through the use of a web browser. Students, researchers and scholars can locate papers, drawings, photographs, experimental data, and books on almost any subject desired. Bank customers can track account balances and conduct financial transactions such as transferring money between accounts and purchasing stocks, bonds, and other securities. Prerecorded music and videos are readily downloaded from appropriate web sites and live performances are routinely broadcast over the Internet. The Internet has impacted virtually every life in one way or another, and new developments are appearing on an almost daily basis.

The rapid growth of the Internet has been accompanied by equally rapid development of new devices. Some of these new devices, such as wireless access points, provide connectivity to the Internet so more people can enjoy the benefits of communicating with others all over the globe. Personal digital assistants (PDAs) are often used in conjunction with Internet access to download email, synchronize scheduling, and update address books, thereby simplifying the lives and increasing the efficiency of end users. Some devices have been developed for entertainment purposes while still others may be used to increase security in residential and business settings. There is seemingly endless creativity in offering new services over the Internet, and there is simultaneously widespread development and deployment of devices to exploit these services.

A problem that arises with the development of so many devices is that they all require a power source in one form or another. Many of these devices, such as wireless access points, remote sensors, and security cameras do not typically have internal batteries and require a continuous connection to an external power source. Furthermore, these devices are often deployed outdoors where installation may require running new power lines. The associated costs can be expensive, have high administrative overhead, and introduce safety concerns because of working with high voltages. Even in locations such as homes and office buildings where power lines already exist, continually adding more Internet enabled devices depletes the number of available wall outlets and often clutters the area with both network and power cabling. Other devices, such as PDAs and digital cameras, which do have batteries, still require occasional connection to a power source to recharge the batteries. With a plethora of devices in a typical household or business environment, coupled with the fact that the chargers for each device are rarely interchangeable, the number of separate chargers further clutters the workspace and the required number of outlets often exceeds the number available. The clutter is further exacerbated by the fact that the convenience of networking capability within the home or office is usually accompanied by a messy distribution of network cables laying along the floor or hanging from ceilings.

To address many of these issues and to provide further enabling capabilities, the power-over-Ethernet (PoE) standard has been developed. Power-over-Ethernet provides physical and electrical specifications for supplying both data and power to devices using existing local-area networking infrastructure. In this framework, power is “injected” onto common Ethernet lines by using PoE power sourcing equipment. Because of the extensive networking infrastructure already in place, cabling is common in and around many buildings, allowing PoE enabled devices to obtain both power and data by tapping in to this vast infrastructure. This capability often eliminates the need to install new power lines, thus reducing costs and overhead, while at the same time increasing simplicity and safety. Obviously, the amount of cabling is also reduced simply because power and data can be transmitted by a single line instead of two separate lines. In addition, the use of power-over-Ethernet provides a universal standard that allows devices to be used all over the world. This could eliminate the need for device manufacturers to support multiple power standards and people could conceivably no longer have to carry bulky and expensive converters while traveling. Furthermore, adopting the PoE standard for charging PoE devices could eliminate the current state of affairs, where every rechargeable device requires a different charger. The benefit would be further reduction of clutter in the home and workplace, accompanied by a reduction in the number of outlets required.

The advent of power-over-Ethernet has also stimulated the development of many new devices. Most notable amongst these devices are IP telephones that carry voice data globally using the vast, but already existing, Internet networking infrastructure. Audio equipment, security cameras, lighting control, clocks, sensors, and even electric razors and guitars have been developed to take advantage of the rapid expansion in the use of power-over-Ethernet.

Unfortunately, despite the extensive infrastructure already in existence that can be used with PoE equipment, there are still many locations where this infrastructure is not already in place. In these locations, installation of PoE can be as cumbersome, expensive, and as dangerous as installing normal wiring.

It can be seen then that there is a need for Power-over-Ethernet (PoE) power sourcing equipment that is connected to an existing power supply and provides pass-through power for additional devices.

### SUMMARY OF THE INVENTION

To overcome the limitations in the prior art described above, and to overcome other limitations that will become apparent upon reading and understanding the present specification, the present invention discloses a Power-over-Ethernet (PoE) power sourcing equipment that is connected to an existing power supply and provides pass-through power for additional devices.

The present invention solves the above-described problems by easing the installation of PoE sourcing equipment in locations where networking infrastructure is not already in place. Further, the PoE sourcing equipment according to an embodiment of the present invention will not monopolize potentially valuable outlets. To further expand the use of many power-over-Ethernet devices at the same location, the appliance allows layered installation to facilitate multiple deployments simultaneously.

A power interface device in accordance with an embodiment of the present invention includes a housing, a first connector, disposed on a first side of the housing, for connecting to a power source, a second connector, disposed on a second side of the housing and coupled to the power source, for providing power to a load device and an Ethernet port, coupled to the housing and coupled to the power source, the Ethernet port being configured for providing only power to an Ethernet device.

In another embodiment of the present invention, a power interface device is provided. The power interface device includes a housing, a first connector, disposed on a first side of the housing, for connecting to a power source, a second connector, disposed on a second side of the housing and coupled to the power source, for providing power to a load device, wherein the second side of the housing is dimensioned to allow direct coupling of the second connector with the first connector of a separate, but substantially similar, power interface device and an Ethernet port, coupled to the housing and coupled to the power source, the Ethernet port being configured for providing power to an Ethernet device.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 illustrates a typical installation of PoE sourcing equipment on an ordinary streetlight that is mounted to utility pole;

FIG. 2 illustrates a typical utility pole and street light prior to the installation of any PoE sourcing equipment;

FIG. 3 shows a more detailed depiction of a typical photocell according to an embodiment of the present invention;

FIG. 4 shows a PoE power-sourcing device according to an embodiment of the present invention;

FIG. 5 illustrates a block diagram that depicts one example of a method for transferring power from external power source to load device according to an embodiment of the present invention;

FIG. 6A shows an example installation of PoE power-sourcing device on a streetlight for supplying power to wireless device mounted on utility pole according to an embodiment of the present invention;

FIG. 6B is a close-up view of photocell attached to PoE power-sourcing device according to an embodiment of the present invention;

FIG. 7 illustrates an installation of the PoE power-sourcing device for powering network camera mounted to utility pole according to an embodiment of the present invention; FIG. 8 illustrates another embodiment of the PoE power-sourcing device according to an embodiment of the present invention; and

FIG. 9 illustrates a PoE power-sourcing device for deployment in a light socket according to an embodiment of the present invention.

### DETAILED DESCRIPTION OF THE INVENTION

In the following description of the embodiments, reference is made to the accompanying drawings that form a part hereof, and in which is shown by way of illustration the specific embodiments in which the invention may be practiced. It is to be understood that other embodiments may be utilized because structural changes may be made without departing from the scope of the present invention.

The present invention provides an appliance for easing the installation of PoE sourcing equipment in locations where networking infrastructure is not already in place, and that will not monopolize potentially valuable outlets. Multiple deployments of the invention may be layered on one another, further conserving outlets.

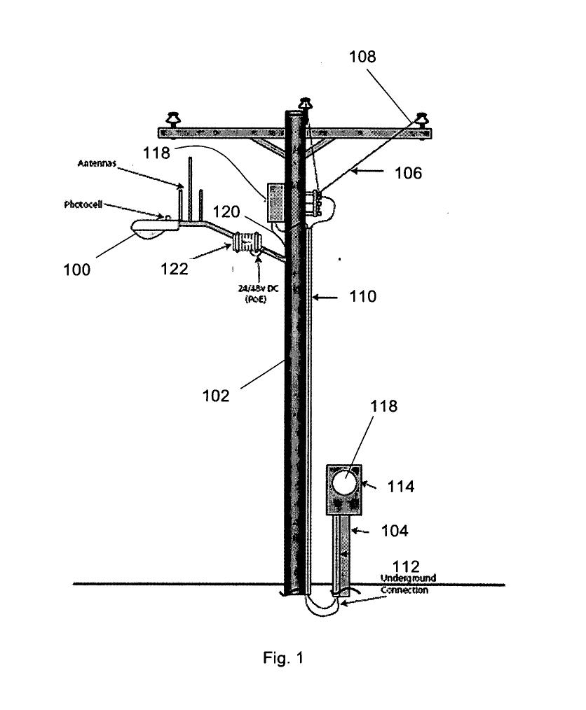

FIG. 1 illustrates a typical installation of PoE sourcing equipment on an ordinary streetlight 100 that is mounted to utility pole 102. In the typical installation of PoE sourcing equipment shown in FIG. 1, the utility company must first be notified before proceeding. This is because streetlight 100 is typically owned by the city, whereas the utility company owns utility pole 102. Once approval is obtained, work permits must be acquired and rights must be granted to place meter pedestal 104 next to utility pole 102. An electrician, approved by the utility company, is then hired to drop a power line 106 from the main line 108 down a conduit 110 where an underground connection 112 is made to the meter box 114. The power line 106 is then returned back up the utility pole 102 through the conduit 110. After receiving approval of the installation from city inspectors, the utility company then places the meter 116, after which an outdoor enclosure 118 is installed on the utility pole 102 for housing the PoE power sourcing equipment. Finally, an Ethernet cable 120 can be run between the enclosure 118 and the powered device 122. It is apparent that the installation process is rather involved and time consuming, typically requiring as much as a month for planning and 1-2 days for installation. Once the PoE sourcing equipment is installed, the benefits of PoE can be enjoyed, but at a much higher level of effort than one would like. Even in places where Ethernet cabling is already in place, injecting power over the existing Ethernet lines requires the use of a separate device that must be plugged into an outlet. Unfortunately, the outlet may already be in use by another device, or its use would preclude further devices from being plugged in. Thus, the installation of PoE sourcing equipment in locations where networking infrastructure is not already in place is very difficult, and often monopolizes potentially valuable outlets.

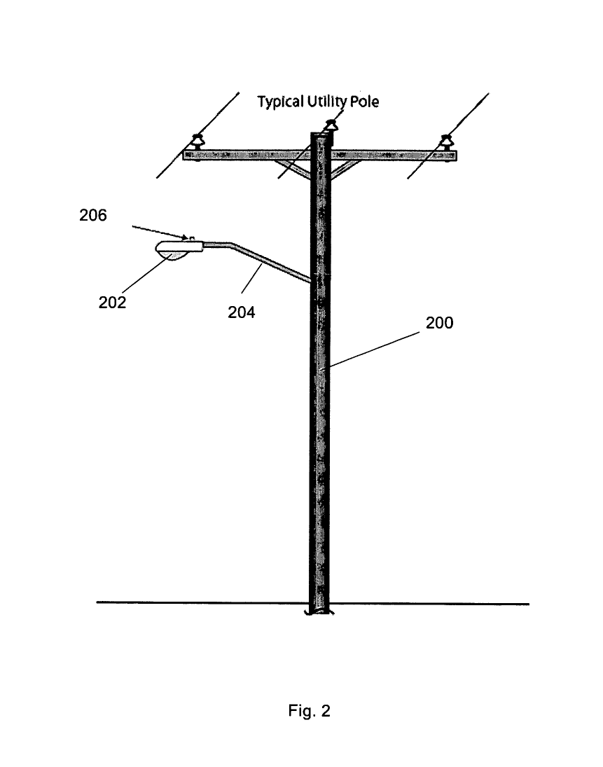

FIG. 2 illustrates a typical utility pole and street light prior to the installation of any PoE sourcing equipment. In FIG. 2, a utility pole 200 including streetlight 202 is mounted to mounting arm 204. Photocell 206 is coupled to the top of streetlight 202 and is used to control power to the streetlight 202, supplying power to the streetlight when ambient lighting is insufficient to light the surrounding area, and not supplying power when ambient lighting is plentiful.

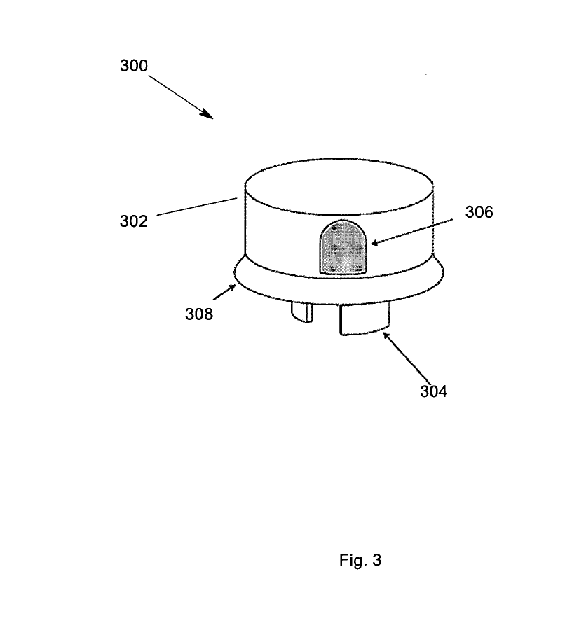

FIG. 3 shows a more detailed depiction of a typical photocell 300 according to an embodiment of the present invention. In FIG. 3, photocell 300 is housed in ANSI C136.10-1996 compliant housing 302 and is coupled to the streetlight (202 in FIG. 2) using an ANSI C136.10-1996 compliant male connector 304. Aperture 306 allows light to pass into the interior of housing 302, where circuitry (not shown) is used to control power to the streetlight. Skirt 308 provides weather resistance by restricting water from entering the housing. Installation of photocell 300 on the streetlight is easily accomplished by simply placing the photocell in an ANSI C136.10 female connector on the streetlight and rotating the photocell ¼ turn, thereby locking it into place on the streetlight. Removal of the photocell is also easily accomplished by reversing the process.

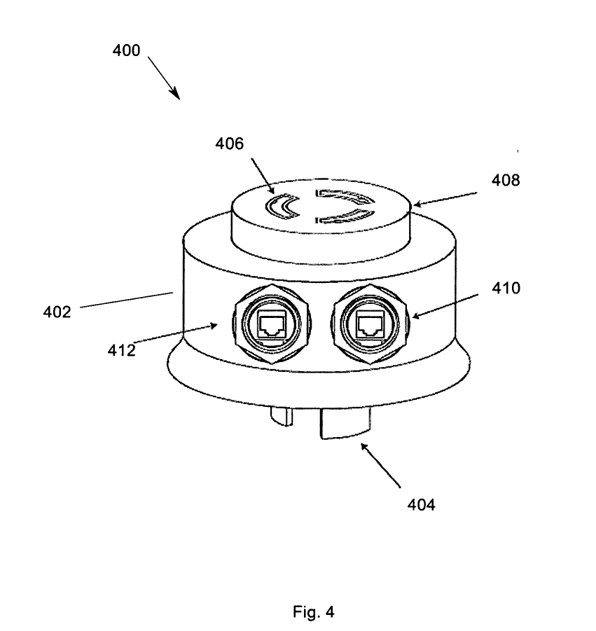

FIG. 4 shows a PoE power-sourcing device 400 according to an embodiment of the present invention. The PoE sourcing device 400 includes ANSI C136.10-1996 compliant housing 402 and is adapted to be attachable to a streetlight using ANSI C136.10-1996 compliant male connector 404, which is located on the bottom of housing 402. An ANSI C136.10-1996 compliant female connector 406 is located on raised connector plate 408 on the top of housing 402. Female connector 406 is used to attach a load device, such as a photocell, to the PoE sourcing device 400. Although ANSI C136.10-1996 male and female connectors are described in the present embodiment, the type of connector is not limiting to the scope of the present invention. Many other types of connectors may be used without altering the invention including, but not limited to, NEMA 5-15R, NEMA 5-15P, standard 1 1/16″ Edison, 1 19/32″ Mogul, ⅝″ Intermediate, ½″ Candelabra, 7/16″ Min-can, ⅜″ Miniature, or any other light bulb screw/socket style. PoE power-sourcing device 400 also includes RJ45 Ethernet port 410 for supplying power to a power-over-Ethernet device. Ethernet port 410 is used to supply power, or optionally both power and data, to an external Ethernet device. PoE power-sourcing device 400 optionally includes one or more RJ45 Ethernet connectors 412 to provide data communication with other devices.

In use, PoE power-sourcing device 400 will be coupled to an external power source, in this embodiment a streetlight, using male connector 404. Power can be transferred from the external power source (not shown in FIG. 4) to female connector 406 for supplying power to a load device such as a photocell (also not shown in FIG. 4) and to Ethernet port 410 using known methodologies which include, but are not limited to, direct or indirect wire connections, power supplies, transformers, micro-controllers, or other circuitry. The appropriate methodology is chosen depending on the power requirements of the load device and the Ethernet port relative to the external power source.

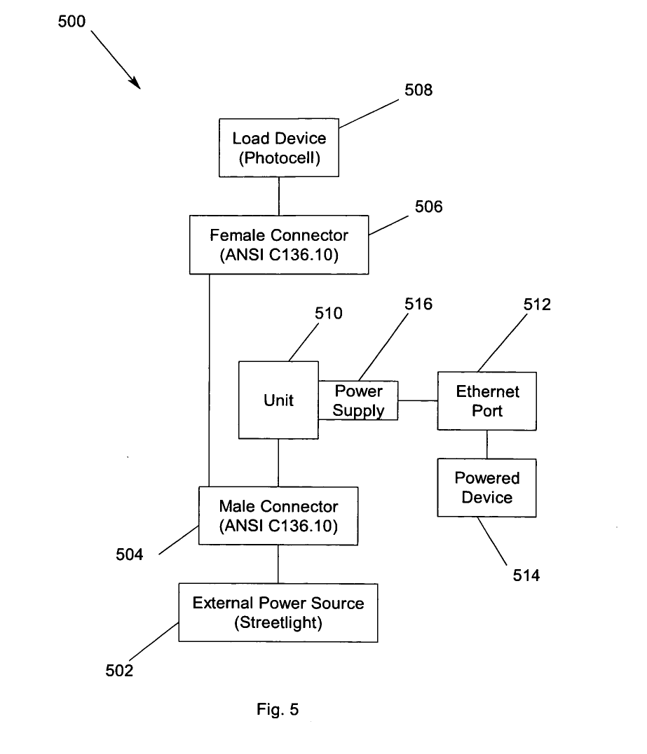

FIG. 5 illustrates a block diagram 500 that depicts one example of a method for transferring power from external power source to load device according to an embodiment of the present invention. In FIG. 5, power from external power source 502 is transferred to load device 508 through ANSI C136.10-1996 female connector 506, as well as to external PoE powered device 514 via Ethernet port 512. In the figure, ANSI C136.10 male connector 504 is coupled to external power source 502 and power is transferred to ANSI C136.10 female connector 506, which may be directly coupled to male connector 504 using only a few wires. Power for Ethernet port 512 is first drawn from external power source 502 via male connector 504 using unit 510, which subsequently provides power supply 516 for supplying suitable power to Ethernet port 512. Although the present embodiment depicts the male connector 504 and female connector 506 being directly coupled, whereas unit 510 couples to male connector 504 to provide power supply 516 for Ethernet port 512, this embodiment is not limiting to the scope of the invention. In other embodiments, female connector 506 and Ethernet port 512 may each be coupled directly to external power supply 502, or they may be indirectly coupled to external power supply 502 through one or more units similar to unit 510 shown in FIG. 5.

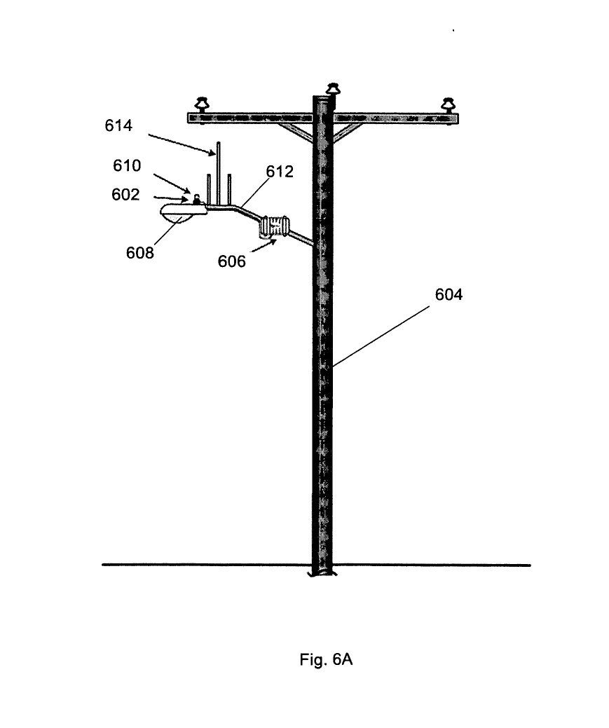

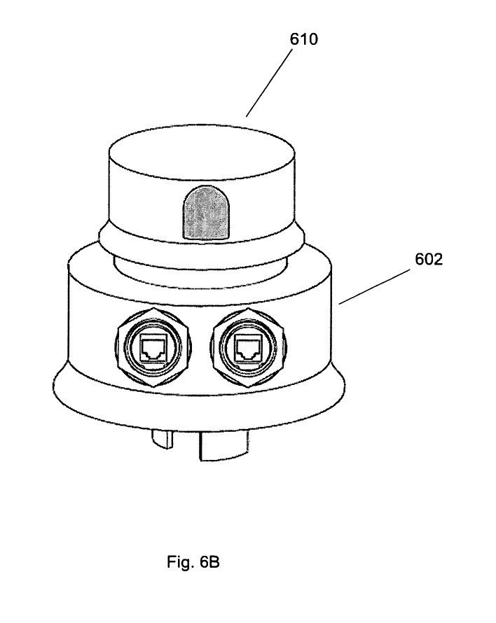

FIG. 6A shows an example installation of PoE power-sourcing device 602 on a streetlight 608 for supplying power to wireless device 606 mounted on utility pole 604 according to an embodiment of the present invention. In the figure, PoE power-sourcing device 602 is attached to streetlight 608 using the ANSI C136.10-1996 compliant male connector 404 depicted previously in FIG. 4. Photocell 610 is coupled to the PoE power-sourcing device using ANSI C136.10 female connector 406, also shown in FIG. 4. Power is supplied to wireless device 606 by inserting one end of Ethernet cable 612 into RJ45 Ethernet port 410 on PoE power-sourcing device 602, and the other end into a similar RJ45 Ethernet port (not shown) on wireless device 606.

FIG. 6B is a close-up view of photocell 610 attached to PoE power-sourcing device 602 according to an embodiment of the present invention. Although the present example shows photocell 610 mounted directly on PoE power-sourcing device 602, this embodiment also allows other devices to be mounted between PoE power-sourcing device 602 and photocell 610. In particular, one or more additional PoE power-sourcing devices may be layered to supply power to one or more additional PoE powered devices. It should also be noted that absence of a load device, such as the photocell in the present example, does not fundamentally change the invention. If a load device is not needed or desired, a cap may be inserted into female connector 406 to provide weatherproofing.

The previous example illustrated the use of an embodiment of the present invention for supplying power to a wireless device mounted to a utility pole. The previously described embodiment is in no way limited to supplying power to wireless devices.

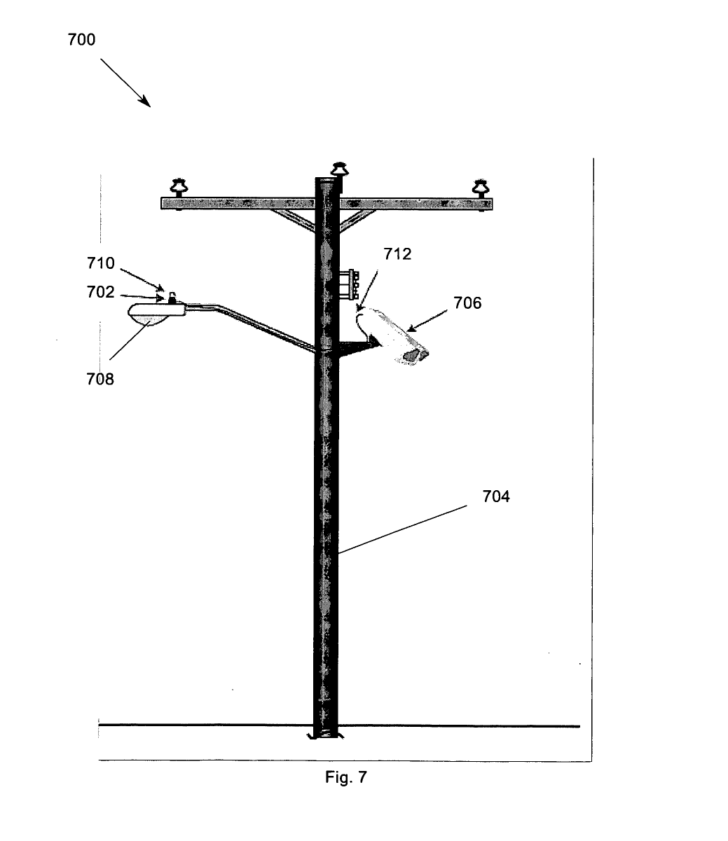

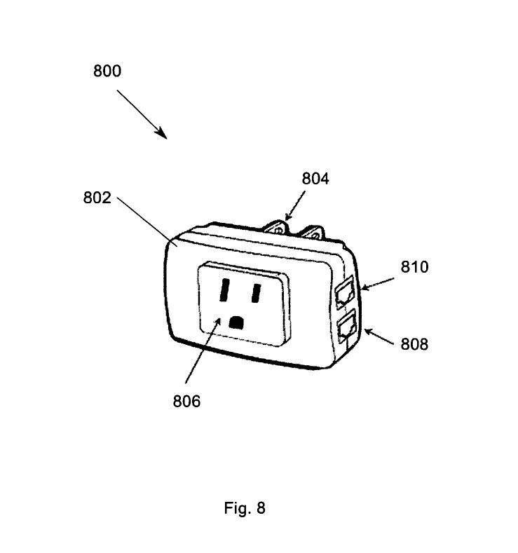

FIG. 7 illustrates an installation 700 of the PoE power-sourcing device for powering network camera mounted to utility pole according to an embodiment of the present invention. PoE power-sourcing device 702 is provided for powering network camera 706 mounted to utility pole 704. Similarly to the previous example of using the PoE power-sourcing device for supplying power to a wireless device, PoE power-sourcing device 702 is attached to streetlight 708 and photocell 710 is subsequently attached to PoE power-sourcing device 702. Power is supplied to network camera 706 by inserting one end of Ethernet cable 712 into PoE power-sourcing device 702, and the other end into network camera 706. Although examples are provided for using the present embodiment of the PoE power-sourcing device of the present invention to supply power to a wireless device and to a network camera mounted to a utility pole, one of ordinary skill in the art would readily recognize that any PoE powered device could obtain power using the PoE power-sourcing device of the present embodiment.

FIG. 8 illustrates another embodiment of the PoE power-sourcing device 800 according to an embodiment of the present invention. In this embodiment, PoE power-sourcing device 800 is to be inserted into a standard wall outlet found in virtually every home or business. In this embodiment, NEMA 5-15P plug 804 is provided on one surface of housing 802 for insertion into the wall outlet (not shown), which, in this embodiment, would have a compatible NEMA 5-15R receptacle. To allow a load device to be attached to PoE power-sourcing device 800, NEMA 5-15R receptacle 806 is provided on a second surface of housing 802. Power is supplied to a PoE powered device through RJ45 Ethernet port 808 whereas optional RJ45 Ethernet port 810 is used for transmitting and receiving data. A second PoE power-sourcing device may optionally be inserted into NEMA 5-15R receptacle 806 before insertion of a load device. By repeatedly installing subsequent PoE power-sourcing devices into previously installed ones, multiple installations of PoE power-sourcing devices similar to PoE power-sourcing device 800 can be located at a single wall outlet to separately supply power to more than one PoE powered device, while still allowing a load device to be inserted and draw power from the last installed PoE power-sourcing device. In the embodiment shown, NEMA 5-15R receptacle 806 is depicted on the opposite surface of housing 802 as NEMA 5-15P plug 804. This configuration is not a requirement and is not limiting to the present invention. A person of ordinary skill in the art easily determines other configurations. The primary requirement is that for successful installation, the second and subsequent PoE power-sourcing devices must have sufficient clearance between the wall and any previously installed PoE power-sourcing devices.

The ANSI C136.10-1996 and NEMA 5-15 connectors described in the previous embodiments are in no way limiting in scope to the present invention. Many other connectors can be utilized without departing from the teachings of the present invention.

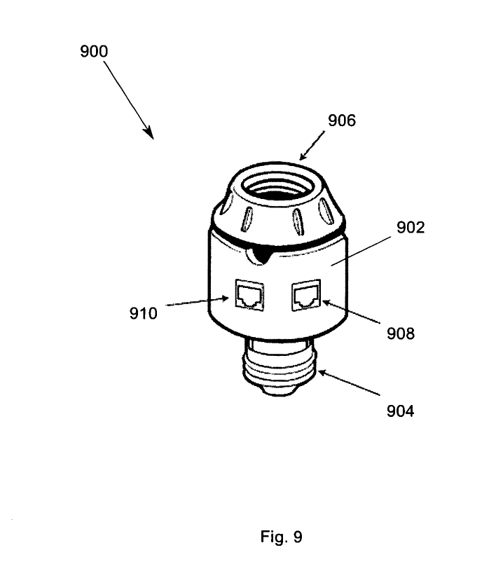

FIG. 9 illustrates a PoE power-sourcing device 900 for deployment in a light socket according to an embodiment of the present invention. In this embodiment, suitable connectors would include, but are not limited by standard 1 1/16″ Edison, 1 19/32″ Mogul, ⅝″ Intermediate, ½″ Candelabra, 7/16″ Min-can, ⅜″ Miniature, and any other light bulb screw/socket style. To connect PoE power-sourcing device 900 to a standard light socket, light bulb screw connector 904 is simply screwed into the light bulb socket on an external lamp or lighting outlet (not shown). A light bulb, or other load device with a light bulb screw connector, can then be screwed into light bulb socket 906. In particular, subsequent PoE power-sourcing devices may be installed by screwing each one into a previously installed PoE power-sourcing device. Power is supplied to power-over-Ethernet powered devices using RJ45 Ethernet port 908. RJ45 Ethernet port 910 can be used to transmit data in and out of device 900 where it is combined with or separated from power on port 908 or as a second power supply port.

The foregoing description of the embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. A power interface device, comprising:
a housing;
a first connector, disposed on a first side of the housing, for connecting to a power source;
a second connector, disposed on a second side of the housing and coupled to the power source, for providing power to a load device; and
an Ethernet port, coupled to the housing and coupled to the power source, the Ethernet port being configured for providing power to an Ethernet device.

2. The power interface device of claim 1, further comprising a unit, coupled to the first connector for drawing power from the power source and for providing power from the power source to the second connector.

3. The power interface device of claim 1, further comprising a unit, coupled to the first connector for drawing power from the power source and for providing power from the power source to the Ethernet port to supply power to the Ethernet device.

4. The power interface device of claim 2, wherein the unit includes a circuit for drawing power from the power source and providing a desired power supply at an output of the first circuit.

5. The power interface device of claim 3, wherein the unit includes a circuit for drawing power from the power source and providing a desired power supply at an output of the first circuit.

6. The power interface device of claim 2, wherein the unit is further configured to provide power to the Ethernet device via the Ethernet port.

7. The power interface device of claim 6, wherein the unit includes a first circuit for drawing power from the power source and providing a desired power supply at an output of the first circuit and a second circuit for drawing power from the output of the first circuit and providing a desired power supply at an output of the second circuit.

8. The power interface device of claim 1, wherein the Ethernet port is weatherproof.

9. The power interface device of claim 6, wherein the Ethernet port is weatherproof.

10. The power interface device of claim 1, wherein the first connector is a male connector and the second connector is a female connector.

11. The power interface device of claim 1, wherein the first connector is selected from the group consisting of ANSI C136.10, NEMA 5-15, 1 1/16″ Edison, 1 19/32″ Mogul, ⅝″ Intermediate, ½″ Candelabra, 7/16″ Min-can, and ⅜″ Miniature.

12. The power interface device of claim 1, wherein the second connector is selected from the group consisting of ANSI C136.10, NEMA 5-15, 1 1/16″ Edison, 1 19/32″ Mogul, ⅝″ Intermediate, ½″ Candelabra, 7/16″ Min-can, and ⅜″ Miniature.

13. A power interface device, comprising:
a housing;
a first connector, disposed on a first side of the housing, for connecting to a power source;
a second connector, disposed on a second side of the housing and coupled to the power source, for providing power to a load device, wherein the second side of the housing is dimensioned to allow direct coupling of the second connector with the first connector of a separate, but substantially similar, power interface device; and
an Ethernet port, coupled to the housing and coupled to the power source, the Ethernet port being configured for providing power to an Ethernet device.

14. The power interface device of claim 13, further comprising a unit, coupled to the first connector for drawing power from the power source and for providing power from the power source to the Ethernet port to supply power to the Ethernet device.

15. The power interface device of claim 14, wherein the unit includes a first circuit for drawing power from the power source and providing a desired power supply at an output of the first circuit.

16. The power interface device of claim 14, wherein the unit is further configured to provide power to the load device.

17. The power interface device of claim 13, wherein the first connector is a male connector and the second connector is a female connector.

18. The power interface device of claim 13, wherein the first connector is selected from the group consisting of ANSI C136.10, NEMA 5-15, 1 1/16″ Edison, 1 19/32″ Mogul, ⅝″ Intermediate, ½″ Candelabra, 7/16″ Min-can, and ⅜″ Miniature.

19. The power interface device of claim 13, wherein the second connector is selected from the group consisting of ANSI C136.10, NEMA 5-15, 1 1/16″ Edison, 1 19/32″ Mogul, ⅝″ Intermediate, ½″ Candelabra, 7/16″ Min-can, and ⅜″ Miniature.
